(19) United States
(12) Patent Application Publication
(10) Pub. No.: US 2025/0385183 A1
(43) Pub. Date: Dec. 18, 2025

(54) CONDUCTIVE STRUCTURE OF COPPER AND ALUMINUM AND FABRICATING METHOD OF THE SAME

(71) Applicant: UNITED MICROELECTRONICS CORP., Hsin-Chu City (TW)

(72) Inventors: Yen-Tsai Yi, Tainan City (TW); Chiao-Hui Tu, Tainan City (TW); Wei-Chuan Tsai, Changhua County (TW); Chuan-Lan Lin, Chiayai City (TW)

(73) Assignee: UNITED MICROELECTRONICS CORP., Hsin-Chu City (TW)

(21) Appl. No.: 18/770,699

(22) Filed: Jul. 12, 2024

(30) Foreign Application Priority Data
Jun. 13, 2024 (TW) 113121857

(51) Int. Cl. H01L 23/532; H01L 21/768

(52) U.S. Cl. CPC H01L 23/53238; H01L 21/76807; H01L 21/76846; H01L 21/76877; H01L 23/53223

(57) ABSTRACT

A conductive structure of copper and aluminum includes an aluminum wire. A first dielectric layer covers the aluminum wire. A contact hole penetrates the first dielectric layer, and a first diffusion block layer fills the contact hole and contacts the sidewall of the contact hole. A first copper wire fills the contact hole. The first diffusion block layer contacts and surrounds the first copper wire. A conductive material layer covers and contacts the aluminum wire and the first diffusion block layer. The conductive material layer includes numerous conductive layers. The work functions of all conductive layers are between 4.1 and 4.6. The conductive layer with the smallest work function among all the conductive layers is closest to the aluminum wire, and the conductive layer with the largest work function among all the conductive layers is closest to the first diffusion block layer.

### BACKGROUND OF THE INVENTION

### 1. Field of the Invention

The present invention relates to a conductive structure of copper and aluminum, and in particular to a conductive structure of copper and aluminum with low resistance and a fabricating method thereof.

### 2. Description of the Prior Art

The manufacturing process of semiconductor integrated circuits is an extremely complex process. The main purpose is to form various electronic components and circuits for a specific circuit onto a small substrate. Each electronic component must be electrically connected through appropriate interconnections to perform expected work. Interconnections can be formed by connecting multiple conductive wires and vias within interlayer dielectric layers.

As semiconductor devices shrink, interconnections must also be reduced in size. Metals used in interconnection result in high resistance in the interconnections. High resistance causes negative effects, such as slowing down electrical signals and increasing the RC constant in a circuit.

### SUMMARY OF THE INVENTION

In view of this, the present invention provides a low-resistance conductive structure and a fabricating process of the same to solve the above problems.

According to a preferred embodiment of the present invention, a conductive structure of copper and aluminum includes a first circuit. The first circuit includes an aluminum wire. A first dielectric layer covers the aluminum wire. A contact hole penetrates through the first dielectric layer. A first diffusion block layer fills the contact hole and contacts a sidewall of the contact hole. A first copper wire fills the contact hole, wherein the first diffusion block layer contacts and surrounds the first copper wire. A conductive material layer covers and contacts the aluminum wire and the first diffusion block layer, wherein the conductive material layer does not contact the sidewall of the contact hole, the conductive material layer includes numerous conductive layers, work functions of all of the conductive layers are between 4.1 and 4.6, the conductive layer with the smallest work function among all the conductive layers is disposed closest to the aluminum wire, and the conductive layer with the largest work function among all the conductive layers is disposed closest to the first diffusion block layer.

According to another preferred embodiment of the present invention, a fabricating method of a conductive structure of copper and aluminum includes provide a substrate. Next, an aluminum material layer and a first conductive material layer are sequentially formed to cover the substrate. Later, the first conductive material layer and the aluminum material layer are patterned to form a conductive material layer and an aluminum wire. After that, a dielectric layer is formed to cover the aluminum wire, the conductive material layer and the substrate. Subsequently, a contact hole is formed to penetrate through the dielectric layer and expose the conductive material layer. Finally, a diffusion block layer and a copper wire are formed sequentially to fill the contact hole, wherein the conductive material layer comprises a plurality of conductive layers, work functions of all of the conductive layers are between 4.1 and 4.6, the conductive layer with the smallest work function among all the conductive layers is disposed closest to the aluminum wire, and the conductive layer with the largest work function among all the conductive layers is disposed closest to the diffusion block layer.

According to another preferred embodiment of the present invention, a conductive structure of copper and aluminum includes an aluminum wire. A first dielectric layer covers the aluminum wire. A contact hole penetrates through the first dielectric layer. A conductive material layer fill the contact hole and contact a sidewall of the contact hole and the aluminum wire. A first diffusion block layer fills the contact hole and contacts the conductive material layer. A first copper wire fills the contact hole, wherein the first diffusion block layer contacts and surrounds the first copper wire. The conductive material layer includes manganese, zirconium, silver, zinc, tungsten, chromium or iron.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 6 depict a fabricating method of a conductive structure of copper and aluminum according to the first preferred embodiment of the present invention, wherein:

FIG. 1 shows an aluminum material layer disposed on a substrate.

FIG. 2 is a fabricating stage following FIG. 1;

FIG. 3 is a fabricating stage following FIG. 2;

FIG. 4 is a fabricating stage following FIG. 3;

FIG. 5 is a fabricating stage following FIG. 4; and

FIG. 6 is a fabricating stage following FIG. 5.

FIG. 7 to FIG. 10 depict a fabricating method of a conductive structure of copper and aluminum according to the second preferred embodiment of the present invention, wherein:

FIG. 7 shows an aluminum wire disposed on a substrate;

FIG. 8 is a fabricating stage following FIG. 7;

FIG. 9 is a fabricating stage following FIG. 8; and

FIG. 10 is a fabricating stage following FIG. 9.

### DETAILED DESCRIPTION

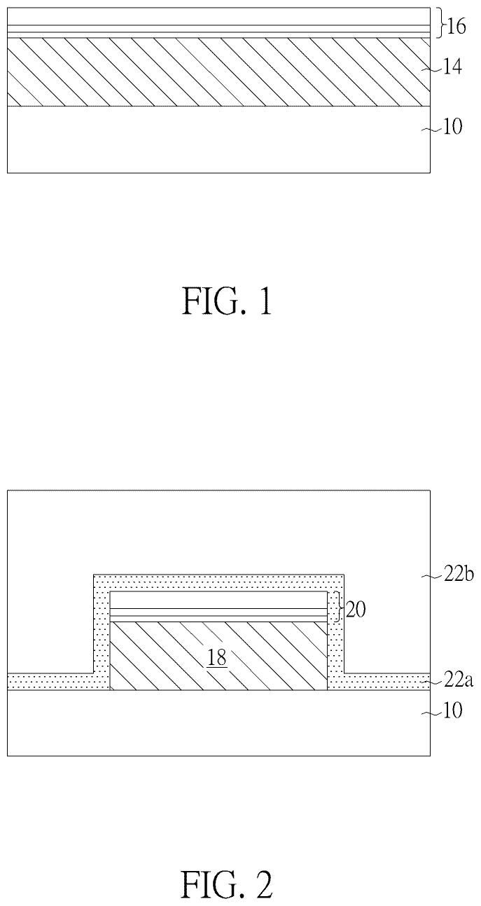

FIG. 1 to FIG. 6 depict a fabricating method of a conductive structure of copper and aluminum according to the first preferred embodiment of the present invention.

As shown in FIG. 1, a substrate 10 is provided. The substrate 10 includes a semiconductor substrate and multiple layers of dielectrics. Multiple layers of dielectrics cover the substrate. A transistor (not shown) is disposed on the semiconductor substrate, and metal interconnections (not shown) of the front end of line process and metal interconnections (not shown) of the back end of line process are disposed in the multiple layers of dielectrics. Then, an aluminum material layer 14 and a first conductive material layer 16 are sequentially formed to cover the substrate 10. The first conductive material layer 16 contacts the aluminum material layer 14. The first conductive material layer 16 and the aluminum material layer 14 can respectively be formed by a physical vapor deposition, a chemical vapor deposition or an atomic layer deposition. As shown in FIG. 2, the first conductive material layer 16 and the aluminum material layer 14 are patterned to form a conductive material layer 20 and an aluminum wire 18. Patterning methods include exposure, development and etching processes. The width of the conductive material layer 20 is the same as the width of the aluminum wire 18. Next, a dielectric layer 22a is formed to conformally cover the conductive material layer 20, the aluminum wire 18 and the substrate 10.

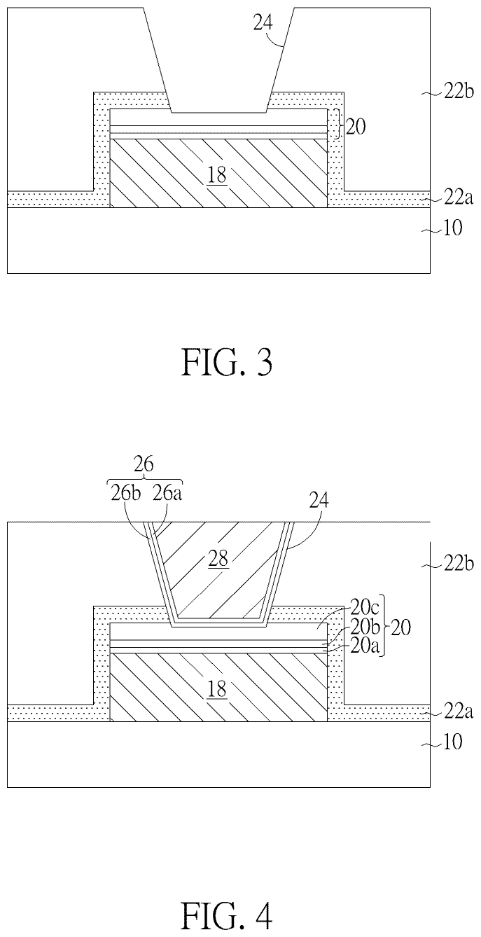

As shown in FIG. 3, a dielectric layer 22b is formed to cover the dielectric layer 22a, the aluminum wire 18, the conductive material layer 20 and the substrate 10. Then, the dielectric layer 22b is etched by using the dielectric layer 22a as an etching stop layer. After that, the dielectric layer 22a is etched to form a contact hole 24 penetrating through the dielectric layer 22b and the dielectric layer 22a, and the conductive material layer 20 is exposed through the contact hole 24. As shown in FIG. 4, a first diffusion block layer 26 and a first copper wire 28 are sequentially formed to fill the contact hole 24. The conductive material layer 20 includes numerous conductive layers. The work function of each of the conductive layers is between 4.1 and 4.6. The conductive layer with the smallest work function among all the conductive layers is disposed closest to the aluminum wire 18. The conductive layer with the largest work function among all the conductive layers is disposed closest to the first diffusion block layer 26. The first diffusion block layer 26 preferably includes tantalum 26a and tantalum nitride 26b. The tantalum 26a contacts the first copper wire 28. The tantalum nitride 26b contacts the conductive material layer 20. According to a preferred embodiment of the present invention, there are three conductive layers 20a/20b/20c in the conductive material layer 20. The conductive layer 20a is made of titanium aluminum alloy (TiAl), the conductive layer 20b is made of titanium, and the conductive layer 20c is made of titanium nitride. Specifically, the fabricating method of the conductive layer includes forming titanium first, and then forming titanium nitride. Because the interface between titanium and aluminum wires will spontaneously generate aluminum-titanium alloy, the conductive layers 20a/20b/20c will include aluminum titanium alloy, titanium and titanium nitride stacked from bottom to top. Aluminum titanium alloy contact aluminum wire 18. Titanium nitride contacts tantalum nitride 26b in first diffusion block layer 26.

According to another preferred embodiment of the present invention, the conductive layer can be a single layer or multiple layers. The conductive layer may include manganese, zirconium, silver, zinc, tungsten, chromium or iron. In this embodiment, the conductive layers 20a/20b/20c are three layers. For example, the conductive layer 20a is made of manganese, the conductive layer 20b is made of silver, and the conductive layer 20c is made of iron. But it is not limited to this, the conductive layer may also be more than three layers.

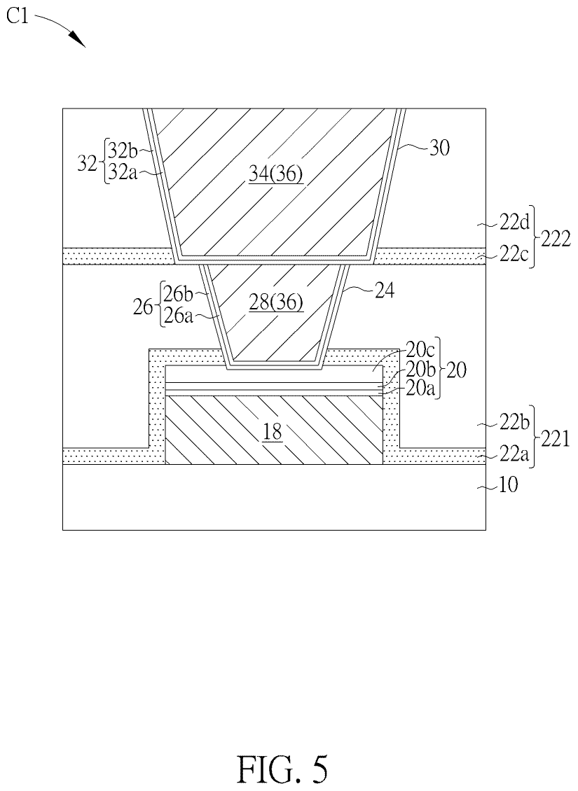

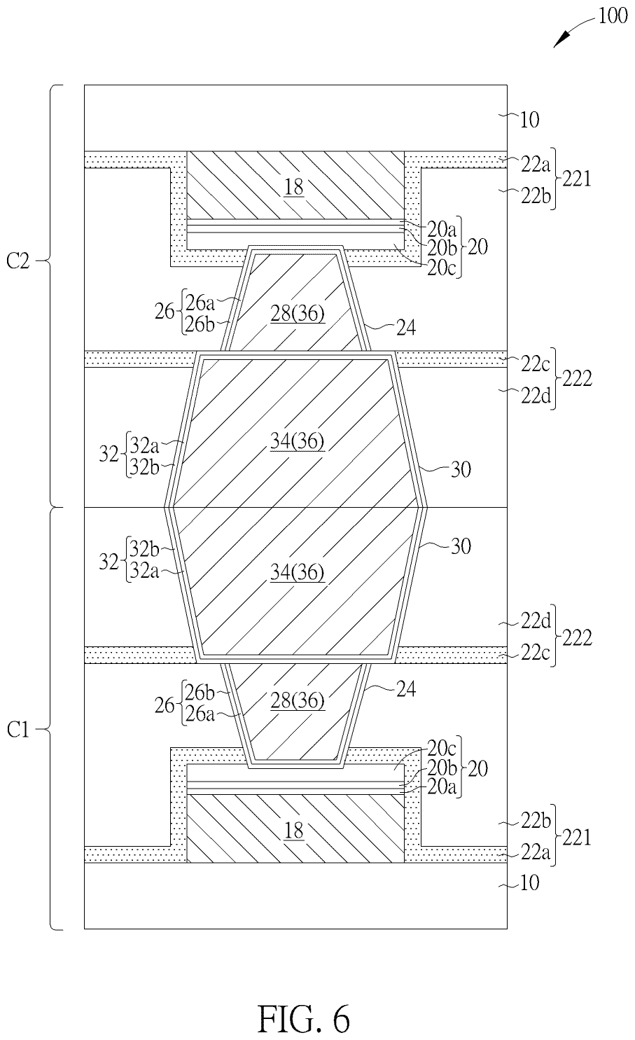

As shown in FIG. 5, a dielectric layer 22c and a dielectric layer 22d are sequentially formed to cover the dielectric layer 22b. Later, the dielectric layer 22d and the dielectric layer 22c are etched to form a trench 30. The trench 30 penetrates through the dielectric layer 22d and the dielectric layer 22c and the first copper wire 28 is exposed through the trench 30. After that, a second diffusion block layer 32 is formed to be disposed in the trench 30 and in contact with the sidewalls of the trench 30. Finally, a second copper wire 34 is formed and is disposed in the trench 30. The second diffusion block layer 32 surrounds the second copper wire 34. The second diffusion block layer 32 is disposed between the top surface of the first copper wire 28 and the bottom surface of the second copper wire 34. The first copper wire 28 and the second copper wire 34 together form a dual damascene structure 36. The second diffusion block layer 32 similarly includes tantalum 32a and tantalum nitride 32b. The tantalum 32a contacts the second copper wire 34. The tantalum nitride 32b contacts the sidewalls of trench 30. Now, the first circuit C1 of the first preferred embodiment is completed. As shown in FIG. 6, a second circuit C2 is provided. The structure of the second circuit C2 and the structure of the first circuit C1 are the same. Later, the second circuit C2 is bonded to the first circuit C1, and the second circuit C2 is electrically connected to the first circuit C1. In details, the dual damascene structure 36 of the second circuit C2 contacts the dual damascene structure 36 of the first circuit C1. Now, a conductive structure of copper and aluminum 100 of the present invention is completed

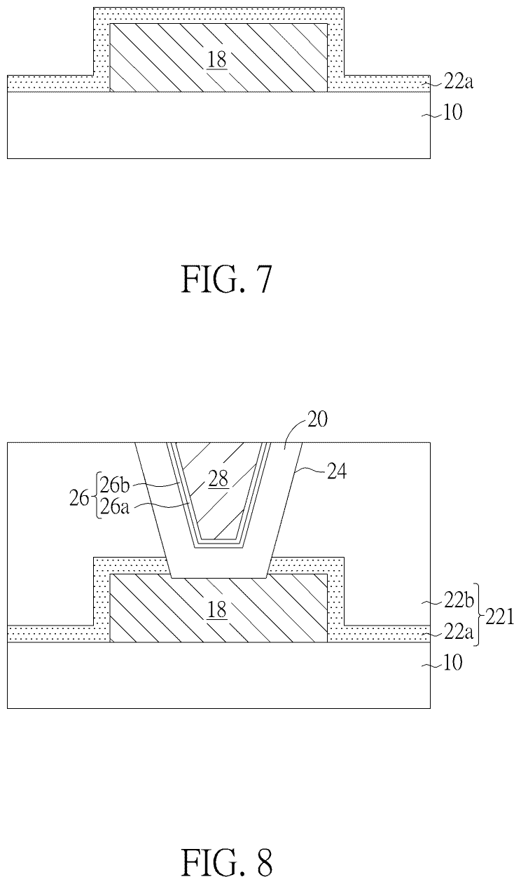

FIG. 7 to FIG. 10 depict a fabricating method of a conductive structure of copper and aluminum according to the second preferred embodiment of the present invention. In the second preferred embodiment, the same elements as those in the first preferred embodiment can include the same material selection and can be completed by using the same method. Therefore, in this preferred embodiment, the material selection and formation method of the elements that are the same as those in the first preferred embodiment will not be described again. In addition, in this preferred embodiment, elements that are the same as those in the first preferred embodiment may include the same reference numerals as those in the first preferred embodiment.

As shown in FIG. 7, a substrate 10 is provided. Later, an aluminum material layer (not shown) is formed to cover the substrate 10. Then, the aluminum material layer is patterned to form an aluminum wire 18. After that, a dielectric layer 22a is formed to conformally cover the aluminum wire 18 and the substrate 10. As shown in FIG. 8, a dielectric layer 22b is formed to cover the dielectric layer 22a. Subsequently, a contact hole 24 is formed to penetrate through the dielectric layer 22b and the dielectric layer 22a and exposes the aluminum wire 18. After that, the conductive material layer 20 is formed to conformally cover the contact hole 24. The conductive material layer 20 includes numerous conductive layers. The work function of each conductive layer is between 4.1 and 4.6. Each conductive layer includes manganese, zirconium, silver, zinc, tungsten, chromium or iron. Next, a first diffusion block layer 26 and a first copper wire 28 fill the contact hole 24. The conductive layer with the smallest work function among all of conductive layers is disposed closest to the aluminum wire 18, and the conductive layer with the largest work function among all the conductive layers is disposed closest to the first diffusion block layer 26.

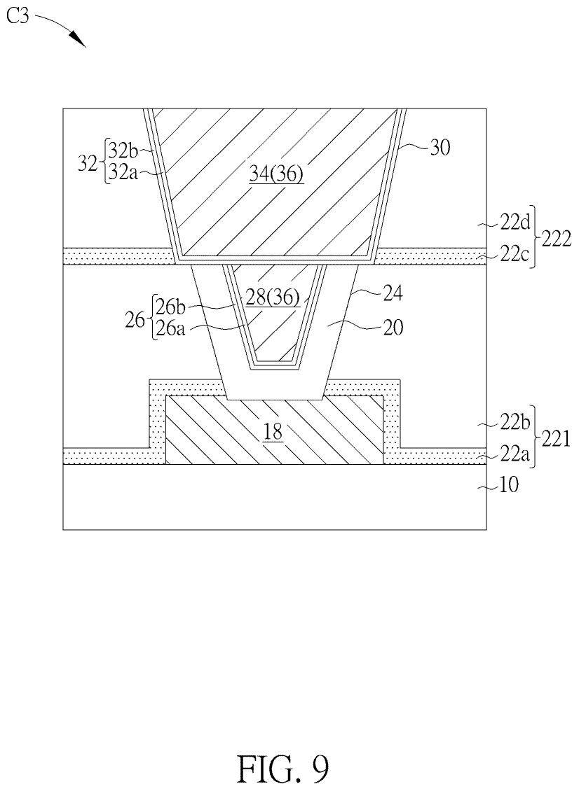

As shown in FIG. 9, a dielectric layer 22c and a dielectric layer 22d are sequentially formed to cover the dielectric layer 22b. Later, the dielectric layer 22d and the dielectric layer 22c are etched to form a trench 30. Next, a second diffusion block layer 32 and a second copper wire 34 are sequentially formed to be disposed in the trench 30. The second diffusion block layer 32 surrounds the second copper wire 34. The second diffusion block layer 32 is located between the top surface of the first copper wire 28 and the bottom surface of the second copper wire 34. The first copper wire 28 and the second copper wire 34 together form a dual damascene structure 36. Now, the first circuit C2 of the second preferred embodiment is completed.

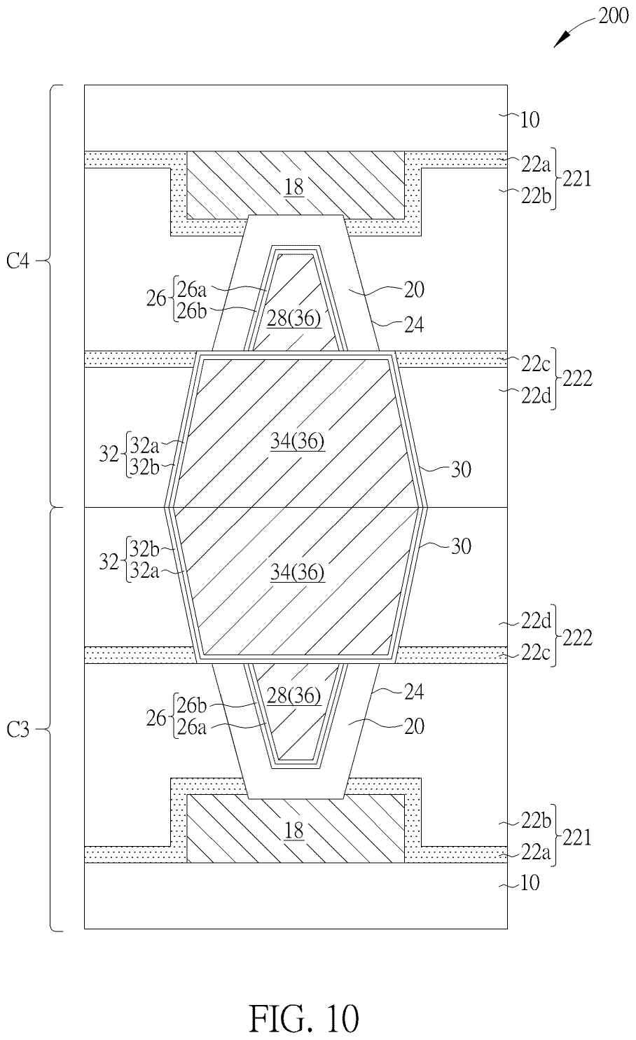

As shown in FIG. 10, a second circuit C4 is provided. The structure of the second circuit C4 and the structure of the first circuit C3 are the same. Later, the second circuit C4 is bonded to and electrically connected with the first circuit C3. Now, a conductive structure of copper and aluminum 200 in the second preferred embodiment is completed.

As shown in FIG. 6, a conductive structure of copper and aluminum 100 includes a first circuit C1 and a second circuit C2, and the first circuit C1 and the second circuit C2 are bonded with each other. Since the structures of the first circuit C1 and the second circuit C2 are the same, only the structure of the first circuit C1 will be described below. The first circuit C1 includes an aluminum wire 18, and the first dielectric layer 221 covers the aluminum wire 18. The first dielectric layer 221 is composed of a dielectric layer 22a and a dielectric layer 22b. The dielectric layer 22a is preferably nitrogen-doped carbon (NDC). The dielectric layer 22b includes silicon oxide, silicon nitride, silicon nitride carbide, silicon oxynitride or silicon carbon oxynitride, etc. A contact hole 24 penetrates through the first dielectric layer 221. A first diffusion block layer 26 fills the contact hole 24 and contacts the sidewall of the contact hole 24. A first copper wire 28 fills the contact hole 24. The first diffusion block layer 26 contacts and surrounds the first copper wire 28. A conductive material layer 20 covers and contacts the aluminum wire 18 and the first diffusion block layer 26. The conductive material layer 20 does not contact the inner sidewall of the contact hole 24. The conductive material layer 20 includes numerous conductive layers, and the work functions of all conductive layers are between 4.1 and 4.6. The conductive layer with the smallest work function among all of conductive layers is disposed closest to the aluminum wire 18, and the conductive layer with the largest work function among all the conductive layers is disposed closest to the first diffusion block layer 26.

According to a preferred embodiment of the present invention, there are three conductive layers, such as conductive layer 20a, a conductive layer 20b and a conductive layer 20c. The conductive layer 20a is made of aluminum titanium alloy, the conductive layer 20b is made of titanium, and the conductive layer 20c is made of titanium nitride. The aluminum titanium alloy contacts the aluminum wire 18, and the titanium nitride contacts the first diffusion block layer 26. According to another preferred embodiment of the present invention, the conductive layer can be a single layer or multiple layers, and the conductive layer may include manganese, zirconium, silver, zinc, tungsten, chromium or iron. In this embodiment, the conductive layers 20a/20b/20c are three layers. But it is not limited to this, the conductive layer may also be more than three layers. Moreover, according to a preferred embodiment of the present invention, the conductive layer 20a is made of manganese, the conductive layer 20b is made of silver, and the conductive layer 20c is made of iron.

In addition, a second dielectric layer 222 covers the first dielectric layer 221. A trench 30 penetrates through the second dielectric layer 222 and exposes the first copper wire 28. The second dielectric layer 222 is composed of a dielectric layer 22c and a dielectric layer 22d. The dielectric layer 22c is preferably nitrogen-doped carbon. The dielectric layer 22d includes silicon oxide, silicon nitride, silicon nitride carbide, silicon oxynitride, or silicon carbon oxynitride. A second diffusion block layer 32 is disposed in the trench 30 and contacts the sidewalls of the trench 30. A second copper wire 34 is disposed in the trench 30. The second diffusion block layer 32 surrounds the second copper wire 34. The first copper wire 28 and the second copper wire 34 together form a dual damascene structure 36.

As shown in FIG. 10, the difference between the conductive structure of copper and aluminum 200 and the conductive structure of copper and aluminum 100 in FIG. 6 is that the conductive material layer 20 of the conductive structure of copper and aluminum 200 is only disposed in the contact hole 24. The conductive material layer 20 only covers a part of the top surface of the aluminum wire 18.

The conductive material layer 20 of the conductive structure of copper and aluminum 100 is below the contact hole 24. The conductive material layer 20 completely covers the top surface of the aluminum wire 18. The bottom surface of the conductive material layer 20 completely overlaps the top surface of the aluminum wire 18. Other elements of the conductive structure of copper and aluminum 200 are the same as that of the conductive structure of copper and aluminum 100, and therefore the description are omitted.

Because the work function of tantalum nitride and the work function of aluminum differ a lot, the resistance of the interface between tantalum nitride and aluminum is large. Therefore, the present invention provides an additional material layer with a work function between 4.1 and 4.6 to be disposed between tantalum nitride and aluminum. In this way, the difference between work functions of tantalum nitride and aluminum can be reduced thereby reducing the resistance between the copper wire and the aluminum wire.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A conductive structure of copper and aluminum, comprising:
a first circuit, comprising:
an aluminum wire;
a first dielectric layer covering the aluminum wire;
a contact hole penetrating through the first dielectric layer;
a first diffusion block layer filling the contact hole and contacting a sidewall of the contact hole;
a first copper wire filling the contact hole, wherein the first diffusion block layer contacts and surrounds the first copper wire; and
a conductive material layer covering and contacting the aluminum wire and the first diffusion block layer, wherein the conductive material layer does not contact the sidewall of the contact hole, the conductive material layer comprises a plurality of conductive layers, work functions of all of the plurality of conductive layers are between 4.1 and 4.6, the conductive layer with the smallest work function among all of the plurality of conductive layers is disposed closest to the aluminum wire, and the conductive layer with the largest work function among all of the plurality of conductive layers is disposed closest to the first diffusion block layer.

2. The conductive structure of copper and aluminum of claim 1, wherein a bottom surface of the conductive material layer completely overlaps a top surface of the aluminum wire.

3. The conductive structure of copper and aluminum of claim 1, wherein the plurality of conductive layers comprises aluminum titanium alloy (TiAl), titanium and titanium nitride, aluminum titanium alloy contacts the aluminum wire, and the titanium nitride contacts the first diffusion block layer.

4. The conductive structure of copper and aluminum of claim 1, wherein the plurality of conductive layers comprise manganese, zirconium, silver, zinc, tungsten, chromium or iron.

5. The conductive structure of copper and aluminum of claim 1, further comprising:
a second dielectric layer covering the first dielectric layer;
a trench penetrating through the second dielectric layer and exposing the first copper wire;
a second diffusion block layer disposed in the trench and contacting a sidewall of the trench; and
a second copper wire disposed in the trench, wherein a second diffusion block layer surrounds the second copper wire, and the first copper wire and the second copper wire together form a dual damascene structure.

6. The conductive structure of copper and aluminum of claim 1, wherein the first diffusion block layer comprises tantalum and tantalum nitride.

7. The conductive structure of copper and aluminum of claim 1, further comprising: a second circuit, wherein a structure of the second circuit is the same as a structure of the first circuit, the second circuit bonds to the first circuit and the second circuit are electrically connected to the first circuit.

8. A fabricating method of a conductive structure of copper and aluminum, comprising:
provide a substrate;
sequentially forming an aluminum material layer and a first conductive material layer covering the substrate;
patterning the first conductive material layer and the aluminum material layer to form a conductive material layer and an aluminum wire;
forming a dielectric layer covering the aluminum wire, the conductive material layer and the substrate;
forming a contact hole penetrating through the dielectric layer and exposing the conductive material layer; and
sequentially forming a diffusion block layer and a copper wire filling the contact hole, wherein the conductive material layer comprises a plurality of conductive layers, work functions of all of the plurality of conductive layers are between 4.1 and 4.6, the conductive layer with the smallest work function among all of the plurality of conductive layers is disposed closest to the aluminum wire, and the conductive layer with the largest work function among all of the plurality of conductive layers is disposed closest to the diffusion block layer.

9. The fabricating method of a conductive structure of copper and aluminum of claim 8, wherein the plurality of conductive layers comprises aluminum titanium alloy (TiAl), titanium and titanium nitride, aluminum titanium alloy contacts the aluminum wire, and the titanium nitride contacts the diffusion block layer.

10. The fabricating method of a conductive structure of copper and aluminum of claim 8, wherein the plurality of conductive layers comprises manganese, zirconium, silver, zinc, tungsten, chromium or iron.

11. A conductive structure of copper and aluminum, comprising:
an aluminum wire;
a first dielectric layer covering the aluminum wire;
a contact hole penetrating through the first dielectric layer;
a conductive material layer filling the contact hole and contacting a sidewall of the contact hole and the aluminum wire;
a first diffusion block layer filling the contact hole and contacting the conductive material layer; and
a first copper wire filling the contact hole, wherein the first diffusion block layer contacts and surrounds the first copper wire; wherein the conductive material layer comprises manganese, zirconium, silver, zinc, tungsten, chromium or iron.

12. The conductive structure of copper and aluminum of claim 11, wherein when seeing from a sectional view, a profile of an entirety of the conductive material layer is conformal to a profile of the contact hole.

13. The conductive structure of copper and aluminum of claim 11, further comprising:
a second dielectric layer covering the first dielectric layer;
a trench penetrating through the second dielectric layer and exposing the first copper wire;
a second diffusion block layer disposed in the trench and contacting a sidewall of the trench; and
a second copper wire disposed in the trench, wherein a second diffusion block layer surrounds the second copper wire, and the first copper wire and the second copper wire together form a dual damascene structure.

14. The conductive structure of copper and aluminum of claim 11, wherein the conductive material layer is only disposed in the contact hole.

15. The conductive structure of copper and aluminum of claim 11, wherein the first diffusion block layer comprises tantalum and tantalum nitride.
